(19) United States
(12) Patent Application Publication
(10) Pub. No.: US 2025/0098410 A1
(43) Pub. Date: Mar. 20, 2025

(54) METHODS FOR MANUFACTURING ELECTRONIC DEVICE

(71) Applicant: InnoLux Corporation, Miao-Li County (TW)

(72) Inventors: Chih-Ming LIANG, Miao-Li County (TW); Yi-An CHEN, Miao-Li County (TW); Feng-Yu LIN, Miao-Li County (TW); Chiung-Chieh KUO, Miao-Li County (TW)

(21) Appl. No.: 18/805,842

(22) Filed: Aug. 15, 2024

(30) Foreign Application Priority Data
Sep. 15, 2023 (CN) 202311192272.1

(51) Int. Cl. H10K 59/12; H10K 59/38; H10K 59/80; H10K 71/00

(52) U.S. Cl. CPC H10K 59/1201; H10K 59/38; H10K 59/8723; H10K 59/873; H10K 59/877; H10K 59/8792; H10K 71/851

(57) ABSTRACT

A method for manufacturing an electronic device is provided. The method includes providing a first substrate. The method further includes forming a bank layer on the first substrate. The bank layer includes a bank wall and a first opening, and the first opening adjacent to the bank wall. The method further includes forming a light conversion layer in the first opening. The method further includes forming a spacer on the bank wall. The method further includes providing a second substrate. The method further includes transferring a plurality of electronic units to the second substrate. The method further includes overlapping the first substrate and second substrate, so that the spacer is located between the first substrate and the second substrate.

### CROSS REFERENCE TO RELATED APPLICATIONS

This application claims priority of China Patent Application No. 202311192272.1 filed on Sep. 15, 2023, the entirety of which is incorporated by reference herein.

### BACKGROUND

### Technical Field

The present disclosure relates to methods for manufacturing an electronic device, and in particular it relates to methods for manufacturing an electronic device with a spacer.

### Description of the Related Art

As the applications for electronic devices continue to advance, the development of display technology is also changing with each passing day. However, in the face of different manufacturing and technical conditions, the requirements for the structure and quality of electronic devices are getting higher and higher, causing the manufacturers of electronic devices to face a variety of challenges.

In some existing electronic devices, inkjet printing spacers are used to provide support between substrates. However, one disadvantage of forming spacers between substrates through inkjet printing is that the throughput of spacers is low, which is not conducive to mass production of electronic devices. In addition, since the shape of the spacer formed using the inkjet printing process is close to having a spherical shape, it may become deformed during the process of joining the two substrates, causing the gap between the substrates to be inconsistent throughout the entire electronic device, affecting the quality of said electronic device.

In summary, although existing electronic devices generally meet their original intended uses, they still do not fully meet the needs of users in all respects. For example, how to improve the mass production of electronic devices while improving the yield rate of electronic devices is still a topic that the industry is currently devoted to researching. Therefore, the research and development of electronic devices requires continuous updates and adjustments to solve various problems faced by the manufacturers of electronic devices.

### BRIEF SUMMARY

The present disclosure provides a method for manufacturing an electronic device. The method includes providing a first substrate. The method further includes forming a bank layer on the first substrate. The bank layer includes a bank wall and a first opening, and the first opening adjacent to the bank wall. The method further includes forming a light conversion layer in the first opening. The method further includes forming a spacer on the bank wall. The method further includes providing a second substrate. The method further includes transferring a plurality of electronic units to the second substrate. The method further includes overlapping the first substrate and second substrate, so that the spacer is located between the first substrate and the second substrate.

The present disclosure provides another method for manufacturing an electronic device. The method includes providing a first substrate. The method further includes forming a bank layer on the first substrate. The bank layer comprises a first opening, a second opening and a bank wall located between the first opening and the second opening. The method further includes forming a light conversion layer in the first opening. The method further includes forming a spacer in the second opening. The method further includes forming an encapsulation layer on the light conversion layer and the spacer. The method further includes providing a second substrate. The method further includes transferring a plurality of electronic units to the second substrate. The method further includes overlapping the first substrate and the second substrate, so that the spacer is located between the first substrate and the second substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion

FIG. 1A illustrates a cross-sectional view of a light conversion structure including a first substrate and a spacer formed on a bank layer for forming an electronic device, in accordance with some embodiments of the present disclosure.

FIG. 1B illustrates a cross-sectional view of a light conversion structure including the first substrate and the spacer formed on the bank layer for forming the electronic device, in accordance with some embodiments of the present disclosure.

FIG. 2 illustrates a cross-sectional view of a light conversion structure including the first substrate and the spacer formed on the bank layer for forming the electronic device, in accordance with some embodiments of the present disclosure.

FIG. 3 illustrates a cross-sectional view of a light conversion structure including the first substrate and the spacer formed on the bank layer for forming the electronic device, in accordance with some embodiments of the present disclosure.

FIG. 4 illustrates a cross-sectional view of a light conversion structure including the first substrate and the spacer formed in the opening of the bank layer for forming the electronic device, in accordance with some other embodiments of the present disclosure.

FIG. 5 illustrates a cross-sectional view of the electronic device formed by overlapping the first substrate and a second substrate, in accordance with some embodiments of the present disclosure.

FIG. 6A illustrates a cross-sectional view of the electronic device formed by overlapping the first substrate and the second substrate, in accordance with some embodiments of the present disclosure.

FIG. 6B illustrates a schematic top view of the electronic device formed by overlapping the first substrate and the second substrate, in accordance with some embodiments of the present disclosure.

FIG. 7A illustrates a cross-sectional view of the electronic device formed by overlapping the first substrate and the second substrate, in accordance with some embodiments of the present disclosure.

FIG. 7B illustrates a schematic top view of the electronic device, in accordance with some embodiments of the present disclosure.

FIG. 8 illustrates a cross-sectional view of a stage in the method for manufacturing the electronic device where the first substrate and the second substrate are cut to form multiple electronic panels, in accordance with some embodiments of the present disclosure.

FIG. 9 illustrates a cross-sectional view of the electronic structure including the second substrate and a spacer formed on a pixel definition layer for forming the electronic device, in accordance with some embodiments of the present disclosure.

FIG. 10 illustrates a cross-sectional view of the electronic device formed by overlapping the first substrate and the second substrate, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about”, “approximately”, and “substantially” used herein generally refer to a given value or a range within 20 percent, preferably within 10 percent, and more preferably within 5 percent, within 3 percent, within 2 percent, within 1 percent, or within 0.5 percent. It should be noted that the amounts provided in the specification are approximate amounts, which means that even “about”, “approximate”, or “substantially” are not specified, the meanings of “about”, “approximate”, or “substantially” are still implied.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The term “substantially” as used herein indicates the value of a given quantity that can vary based on a particular technology node associated with the subject semiconductor device. In some embodiments, based on the particular technology node, the term “substantially” can indicate a value of a given quantity that varies within, for example, ±5% of a target (or intended) value.

In the present disclosure, the measurements for length, thickness, width, height, distance and area may be employed with an optical microscope (OM), an electron microscope (such as a scanning electron microscope (SEM)) or other suitable methods, but not limited thereto.

It should be understood that the electronic device of the present disclosure may include a display device, a backlight device, an antenna device, a sensing device or a splicing device, but it is not limited thereto. The electronic device may be a bendable or flexible electronic device. The display device may be a non-self-luminous display device or a self-luminous display device. The antenna device may be a liquid crystal type antenna device or a non-liquid crystal type antenna device, and the sensing device may be a sensing device that senses capacitance, light, heat energy or ultrasonic waves, but it is not limited thereto. The electronic unit may include passive components and active components, such as capacitors, resistors, inductors, diodes, transistors, etc. Diodes may include light-emitting diodes or photodiodes. The light-emitting diodes may include, for example, organic light-emitting diodes (OLEDs), submillimeter light-emitting diodes (mini LEDs), micro light-emitting diodes (micro LEDs) or quantum dot light-emitting diodes (quantum dot LED), but it is not limited thereto. The splicing device may be, for example, a display splicing device or an antenna splicing device, but it is not limited thereto. It should be noted that the electronic device can be any combination of the above, but it is not limited thereto. In the following, a display device will be used as an electronic device or a splicing device to illustrate the contents of the present disclosure, but the present disclosure is not limited thereto.

The present disclosure provides a method for manufacturing an electronic device. A spacer is formed on a bank layer or in an opening of the bank layer, so that the spacer is located between two substrates of the resulting electronic device. Compared with traditional electronic devices that use inkjet printing technology to form spacers, since the spacers of the present disclosure have a greater elastic recovery rate, their shapes are not easily deformed when joining the two substrates. As a result, the spacer can provide stable and uniform support throughout the entire electronic device, thereby improving the quality and yield of the electronic device. In addition, by forming spacers between substrates through the method of the present disclosure, electronic devices can be manufactured with greater throughput, which is beneficial to mass production of electronic devices. Therefore, the present disclosure provides a method for manufacturing an electronic device that can improve the mass production of the electronic device while improving the quality and yield of the electronic device.

The method for manufacturing the electronic device of the present disclosure may include joining a light conversion structure and an electronic structure, wherein the light conversion structure includes a first substrate and a light conversion layer thereon, and the electronic structure includes a second substrate and a plurality of electronic units thereon. In addition, the method further includes formation of a spacer so that the spacer is located between the first substrate and the second substrate. Various aspects of the method for manufacturing the electronic device of the present disclosure will be described below with reference to the drawings. It should be understood that although the embodiments of the present disclosure are described in detail with reference to the drawings, the specific configuration is not limited to the following embodiments, and various improvements and design changes that do not deviate from the gist of the present disclosure are also included within the range of the present disclosure. Therefore, features of various embodiments may be mixed and matched as long as they do not violate the spirit of the invention or conflict with each other.

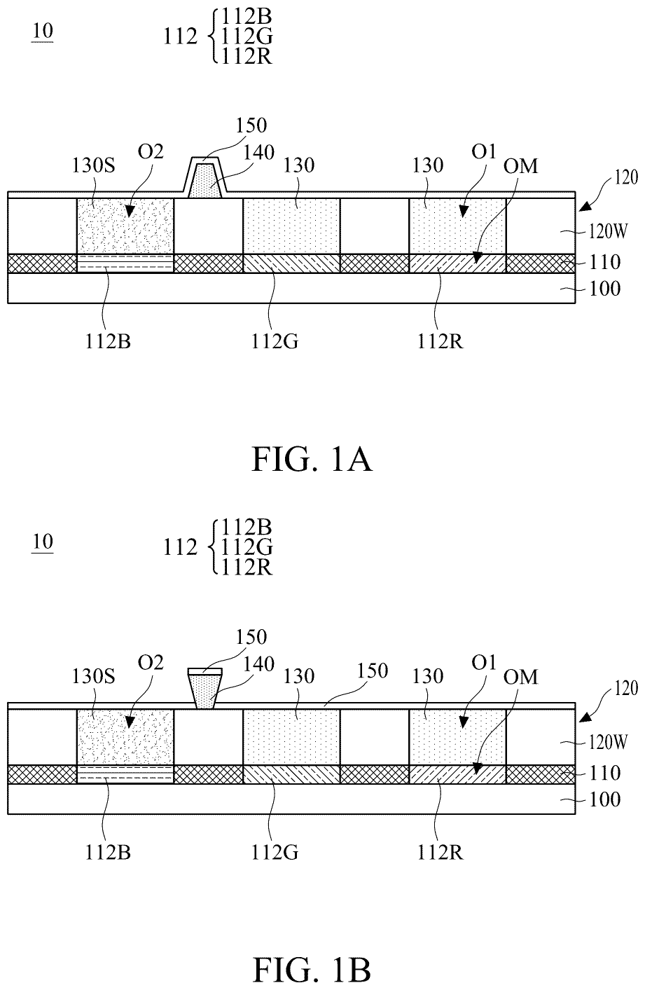

FIG. 1A illustrates a cross-sectional view of a light conversion structure 10 including a first substrate 100 and a spacer 140 formed on a bank layer 120 for forming an electronic device, in accordance with some embodiments of the present disclosure. The formation of the light conversion structure 10 includes providing the first substrate 100 and forming the bank layer 120 on the first substrate 100. As shown in FIG. 1A, the bank layer 120 may include a bank wall 120W and a first opening O1. The first opening O1 neighbors the bank wall 120W, and the light conversion layer 130 may be formed in the first opening O1. Then, in some embodiments, the spacer 140 is formed on the bank wall 120W.

The substrate 100 may include transparent or opaque organic materials or inorganic materials. Organic materials may include, for example, polyimide (PI), polycarbonate (PC), polyethylene terephthalate (PET), liquid crystal polymer (LCP), other suitable materials or combinations of the above materials, but not limited thereto. Inorganic materials may include, for example, dielectric materials, metallic materials, other suitable materials, or combinations of the above materials, but are not limited thereto. In addition, the substrate 100 may include rigid materials or flexible materials. Rigid materials may include glass, quartz, sapphire, ceramics, plastics, other suitable materials, or combinations of the above materials, but are not limited thereto. Flexible materials here refer to materials that can be curved, bent, folded, rolled, flexible, stretched and/or can undergo other similar deformations. Examples of flexible materials may include one of the above-mentioned organic materials, but the flexible materials referred to in the present disclosure are not limited to the above-mentioned materials, and the term “flexibility” is not limited to the above-mentioned deformation methods.

The bank wall 120W may include an opaque material. According to some embodiments, the bank wall 120W can absorb light emitted by the electronic structure or absorb ambient light, making it difficult for the light to pass through, thereby improving the display quality of the resulting electronic device, but is not limited to this. According to some other embodiments, the bank wall 120W can reflect the light emitted by the electronic structure or reflect ambient light, so that the light emitted by the electronic structure or the ambient light is transmitted to the first opening of the bank layer 120 to improve the light usage efficiency, but not limited thereto.

The material of the bank wall 120W may include, for example, black resin, gray resin, white resin, metal, other suitable materials, or a combination of the above materials, but it is not limited thereto. The formation method of the bank layer 120 may include physical vapor deposition (PVD), chemical vapor deposition (CVD), atomic layer deposition (ALD), electron beam evaporation, electroplating, inkjet printing, sol-gel method, spin coating (spin coating), other suitable methods, or a combination thereof, but not limited to this. In some embodiments, the bank wall 120W is formed using a lithography process, but the present disclosure is not limited thereto. The lithography process may include photoresist coating (e.g., spin coating), soft baking, mask alignment, exposure, post-exposure baking, photoresist development, rinsing, drying (e.g., spin-drying and/or hard baking), other suitable lithography steps, and/or a combination thereof.

In some embodiments, as shown in FIG. 1A, before forming the bank 120 on the first substrate 100, a black matrix layer 110 including a matrix opening OM is formed on the first substrate 100. Then, a color filter layer 112 may be formed in the matrix opening OM. In some embodiments, as shown in FIG. 1A, the black matrix layer 110 is sandwiched between the first substrate 100 and the bank layer 120. Although top surfaces of the black matrix layer 110 and the color filter layer 112 are shown as co-planar in FIG. 1A, the present disclosure is not limited thereto. In other embodiments, the top surface of the color filter layer 112 may be higher or lower than the top surface of the black matrix layer 110.

The material of the black matrix layer 110 may include black photoresist, black ink, other suitable materials, or a combination of the above materials, but it is not limited thereto. The formation method of the black matrix layer 110 may include physical vapor deposition (PVD), chemical vapor deposition (CVD), atomic layer deposition (ALD), electron beam evaporation, electroplating, inkjet printing, sol-gel method, photoresist coating, other suitable methods, or a combination thereof, but not limited to this.

The color filter layers 112 in the matrix openings OM may be color filter layers corresponding to various wavelength ranges. In some embodiments, as shown in FIG. 1, the color filter layers 112 includes a blue filter layer 112B, a green filter layer 112G, and a red filter layer 112R corresponding to blue, green, and red light bands respectively, but not limited to this. In some embodiments, the color filter layer 112 includes a filter material having a specific filtering band. In some embodiments, the color filter layer 112 may include a scattering layer, optical clear adhesive, other suitable materials, or a combination of the above materials, but it is not limited thereto.

In addition, the present disclosure does not limit the formation order of the color filter layer 112 and the spacer 140. In some embodiments, by forming the color filter layer 112 before forming the spacer 140, materials for the spacer 140 can be avoided from being deposited into the matrix openings OM. In some other embodiments, by forming the color filter layer 112 after forming the spacer 140, the high-temperature process used to form the spacer 140 can be avoided from degrading the color filter layer 112. The formation method of the color filter layer 112 may include chemical vapor deposition (CVD), inkjet printing, sol-gel method, photoresist coating, other suitable methods, or a combination thereof, but it is not limited thereto.

Likewise, the present disclosure does not limit the formation order of the light conversion layer 130 and the spacer 140. A person with ordinary skill in the art may decide to form the light conversion layer 130 before or after forming the spacer 140 according to design requirements. In some embodiments, by forming the light conversion layer 130 after forming the spacer 140, it is possible to avoid the high-temperature process used to form the spacer 140 from degrading the light conversion properties of the light conversion layer 130. In addition, the spacer 140 formed under higher temperature conditions (e.g., about 220° C. to 230° C.) can have a better elastic recovery rate and is less likely to deform during the substrate joining process. In some other embodiments, by forming the light conversion layer 130 before forming the spacer 140, the influence of the process for the spacer on the process of the light conversion layer 130 can be reduced. Therefore, referring to FIG. 1A, in the embodiments in which the spacer 140 is formed on the bank layer 120, a person with ordinary skill in the art may decide to form the light conversion layer 130 before or after forming the spacer 140 according to the design requirements. This is not limited in this embodiment.

As shown in FIG. 1A, the light conversion layers 130 may be formed on the color filter layer 112. In some embodiments, the light conversion layers 130 are only formed in the first openings O1 on the green filter layer 112G and the red filter layer 112R, and the light conversion layers 130 are not formed on the blue filter layer 112B. The light conversion layer 130 may be a material for light conversion including, for example, nanocrystals, but it is not limited thereto. Specific examples of the shape of the nanocrystals include spherical, ellipsoidal, pyramidal, dish-shaped, dendritic, network-shaped or any irregular shapes, other suitable shapes, or combinations thereof, but not limited to this. In a specific embodiment, the light conversion layer 130 includes particle-like quantum dots. The material of the light conversion layer 130 may include SiO₂, ZrO₂, TiO₂, Al₂O₃, In₂O₃, ZnO, SnO₂, Sb₂O₃, other suitable materials or combinations of the above materials, but it is not limited thereto. In some embodiments, the light conversion layer 130 is formed using an inkjet printing process, but it is not limited thereto. The formation method of the light conversion layer 130 may also include chemical vapor deposition (CVD), atomization spraying, sol-gel method, photoresist coating, other suitable methods, or a combination thereof, but it is not limited thereto.

In some embodiments, the bank layer 120 further includes a second opening O2, and a scattering layer 130S is formed in the second opening O2. As shown in FIG. 1A, the light conversion layer 130 may be formed in the first opening O1 and the scattering layer 130S may be formed in the second opening O2. In some embodiments, the first opening O1 is located directly above the green filter layer 112G and the red filter layer 112R corresponding to green light and red light, and the second opening O2 is located directly above the blue filter layer 112B corresponding to blue light. A person with ordinary skill in the art may adjust the positional relationship between the first opening O1 and the second opening O2 and each color filter layer 112 according to the design requirements of the electronic device. In some other embodiments, the light conversion layer 130 instead of the scattering layer 130S can also be formed directly above the blue filter layer 112B. In addition, the present disclosure does not limit the formation order of the scattering layer 130S and the spacer 140. A person with ordinary skill in the art may decide to form the scattering layer 130S before or after forming the spacer 140 according to design requirements.

The material of the scattering layer 130S may include a binder composition such as resin and a plurality of light-absorbing particles or light-scattering particles. The average particle size of the light-absorbing particles or light-scattering particles in the binder composition for the scattering layer 130S may be between 200 nm and 500 nm, and the content of particles with particle sizes of 600 nm or above may account for less than about 20% by volume relative to the total amount of the light-absorbing particles or the light-scattering particles, but it is not limited thereto. In some embodiments, the refractive index difference between the binder composition and the light-absorbing particles or the light-scattering particles is greater than 0.1.

The material of the above-mentioned binder composition may include polycarbonate (PC), polystyrene (PS), polyether, polyester, polyarylate, polyamide, phenolic resin (phenol resin), polyethylene glycol alcohol bisallyl carbonate, acrylonitrile-styrene copolymer (AS resin), methyl methacrylate-styrene copolymer (MS resin), poly-4-methylpentene, norbornene polymer, polyurethane resin, epoxy resin, acrylic resin, and silicone resin, other suitable materials or combinations of the above materials, but it is not limited thereto.

The above-mentioned light-absorbing particles or light-scattering particles may include organic particles or inorganic particles. The material of the organic particles may include polymethyl methacrylate, styrene acrylate copolymer, melamine resin, polycarbonate, polystyrene, cross-linked polystyrene, polyvinyl chloride, benzomelamine-melamine formaldehyde condensate, other suitable materials or combinations of the above materials, but not limited thereto. The material of the inorganic particles may include SiO₂, ZrO₂, TiO₂, Al₂O₃, In₂O₃, ZnO, SnO₂, Sb₂O₃, other suitable materials or combinations of the above materials, but it is not limited thereto. The formation method of the scattering layer 130S may include inkjet printing, sol-gel method, photoresist coating, other suitable methods, or a combination thereof, but it is not limited thereto.

Then, continuing to refer to FIG. 1A, the spacer 140 formed on the bank wall 120W can provide stable and uniform support throughout the entire electronic device, thereby improving the yield of the electronic device. The elastic recovery rate of the spacer 140 may be between about 35% and 65%, where the elastic recovery rate is defined as the recovery displacement/the total compression displacement of the material. The stress intensity factor (K value) of the spacer 140 is about 10-100 mN/μm, such as 10-15 mN/μm.

The material of the spacer 140 may include polyimide, polyamide, acrylic, benzocyclobutene and phenolic resin, polymethylmethacrylate (PMMA), other suitable materials or a combination of the above materials, but not limited to this. In some embodiments, the spacer 140 is formed using a lithography process, but it is not limited thereto. The lithography process may include photoresist coating (e.g., spin coating), soft bake, mask alignment, exposure, post-exposure bake, photoresist development, rinsing, drying (e.g., spin drying and/or hard bake, other suitable lithography steps, and/or combinations thereof. In embodiments where the spacers 140 are formed before the light conversion layer 130 is formed, the process temperature of the spacer 140 may be, for example, between about 220° C. and 230° C., so that the resulting spacer 140 can have a better elastic recovery rate and is less likely to be deformed during the process of joining the substrates.

The cross-sectional shape of the spacer 140 may be a rectangle, a trapezoid, a semicircle, another suitable shape, or a combination thereof. It should be understood that the cross-sectional shape of the spacer 140 depends on the conditions of the process used to form the spacer 140. Specifically, the cross-sectional shape of the spacer 140 may be affected by the reflow properties of the material used for the spacer 140. In addition, in the embodiment in which the spacer 140 is formed using a photolithography process, the cross-sectional shape of the spacer 140 also depends on whether a photo-curing step is performed after the development step.

Then, referring to FIG. 1A, an encapsulation layer 150 may be formed on the light conversion layer 130 and the spacer 140. The encapsulation layer 150 may be deposited to conformally extend over light conversion layer 130 and spacer 140. By forming the encapsulation layer 150, water vapor can be prevented from entering the light conversion layer 130 and performance degradation of the light conversion layer 130 can be avoided. In some embodiments, the encapsulation layer 150 is formed of a transparent encapsulation material. The material of the encapsulation layer 150 may include SiNₓ, SiOₓ, SiOₓN_{y}, other suitable materials, or a combination of the above materials, but it is not limited thereto. The formation method of the encapsulation layer 150 may include physical vapor deposition (PVD), chemical vapor deposition (CVD), atomic layer deposition (ALD), electron beam evaporation, electroplating, sol-gel method, photoresist coating, other suitable methods, or a combination thereof, but not limited to this.

In some embodiments, before forming the encapsulation layer 150, plasma treatment may be performed to make the surfaces of the bank layer 120, the light conversion layer 130 and other film layers hydrophobic. As a result, the adhesion between the encapsulation layer 150 and the underlying materials can be improved and the encapsulation layer 150 can be prevented from peeling off. The present disclosure does not limit the process parameters of the plasma treatment. A person with ordinary skill in the art may adjust the power, processing time and other parameters of the plasma treatment according to the design requirements.

FIG. 1B illustrates a cross-sectional view of the light conversion structure 10 including the first substrate 100 and the spacer 140 formed on the bank layer 120 for forming the electronic device, in accordance with some embodiments of the present disclosure. The light conversion structure 10 shown in FIG. 1B is similar to the light conversion structure 10 shown in FIG. 1A, and the main difference lies in the cross-sectional shape of the spacer 140. Specifically, the cross-sectional shape of the spacer 140 shown in FIG. 1A is a trapezoid, and the cross-sectional shape of the spacer 140 shown in FIG. 1B is an inverted trapezoid. Here, the so-called inverted trapezoidal shape means that the bottom surface of the spacer 140 in contact with the bank layer 120 is smaller than the top surface away from the bank layer 120. In some embodiments, as shown in FIG. 1B, the encapsulation layer 150 covers the top surface of the spacer 140 while exposing the sidewalls of the spacer 140. By forming the cross-sectional shape of the spacer 140 into an inverted trapezoid, generation of cracks in the encapsulation layer 150 during subsequent substrate joining and influence on the elastic properties of the spacer 140 can be avoided.

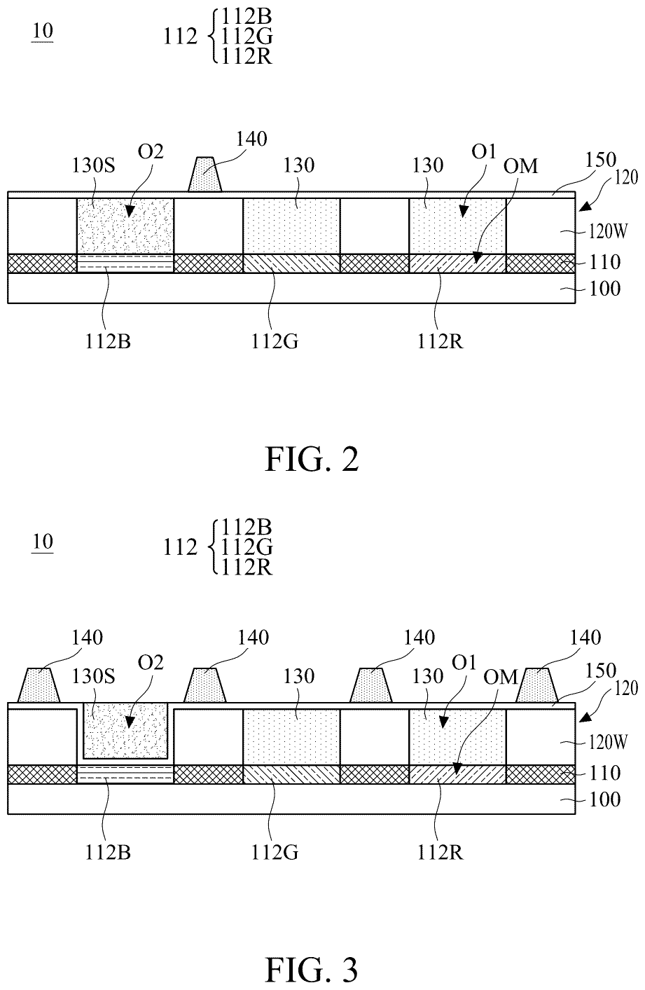

FIG. 2 illustrates a cross-sectional view of the light conversion structure including the first substrate 100 and the spacer 140 formed on the bank layer 120 for forming the electronic device, in accordance with some embodiments of the present disclosure. The main difference between the light conversion structures 10 shown in FIG. 2 and FIGS. 1A and 1B is that the formation order of the spacer 140 and the encapsulation layer 150 is different. Specifically, in the embodiment shown in FIG. 2, before forming the spacer 140 on the bank layer 120, further including forming the encapsulation layer 150 on the bank wall 120W and the light conversion layer 130. As a result, the encapsulation layer 150 is located between the bank layer 120 and the spacer 140 in a direction perpendicular to the first substrate 100. In such an embodiment, the spacer 140 is formed after the light conversion layer 130 is formed. In order to avoid the degradation of the light conversion layer 130, the spacer 140 may be formed at a lower process temperature. For example, the maximum process temperature of the spacer 140 may be less than 120° C. In the embodiment shown in FIG. 2, the materials and formation methods of the spacer 140 and the encapsulation layer 150 may be the same as or similar to those in the embodiment shown in FIGS. 1A and 1B, and their description is omitted here for the sake of simplicity.

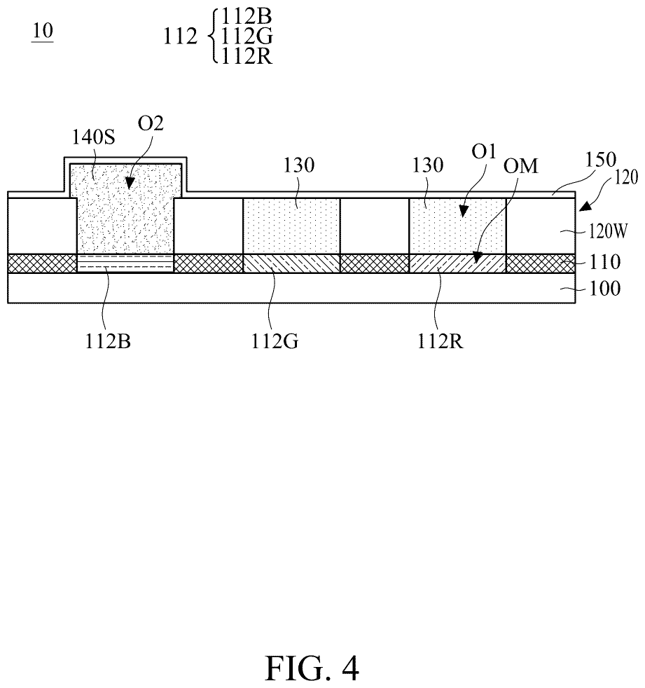

FIG. 3 illustrates a cross-sectional view of the light conversion structure 10 including the first substrate 100 and the spacer 140 formed on the bank layer 120 for forming the electronic device, in accordance with some embodiments of the present disclosure. As shown in FIG. 3, before forming the spacer 140 on the bank wall 120W, it further includes forming the encapsulation layer 150 on the bank layer 120 and the light conversion layer 130 and in the second opening O2. Then, the scattering layer 130S may be formed on the portion of the encapsulation layer 150 located in the second opening O2. In some embodiments, the material and formation method of the spacer 140 are the same as or similar to those in the embodiments shown in FIGS. 1A and 1B. In some other embodiments, the spacer 140 and the scattering layer 130S include the same or similar materials. For example, the materials of the spacer 140 and the scattering layer 130S may include the above-mentioned binder composition of resin for the scattering layer 130S and the light-absorbing particles or the light-scattering particles, the details of which are omitted here for the sake of simplicity.

In addition, in some embodiments, the spacer 140 and the scattering layer 130S are formed in the same photolithography process. As a result, after the encapsulation layer 150 is formed, the scattering layer 130S and the spacer 140 may be formed in a combined process, thereby reducing the manufacturing cost of the light conversion structure 10 and shortening the process period. The lithography process used to form the spacer 140 and the scattering layer 130S together may be similar to the above-mentioned lithography process used to form the spacer 140, and its detailed description is omitted here for the sake of simplicity.

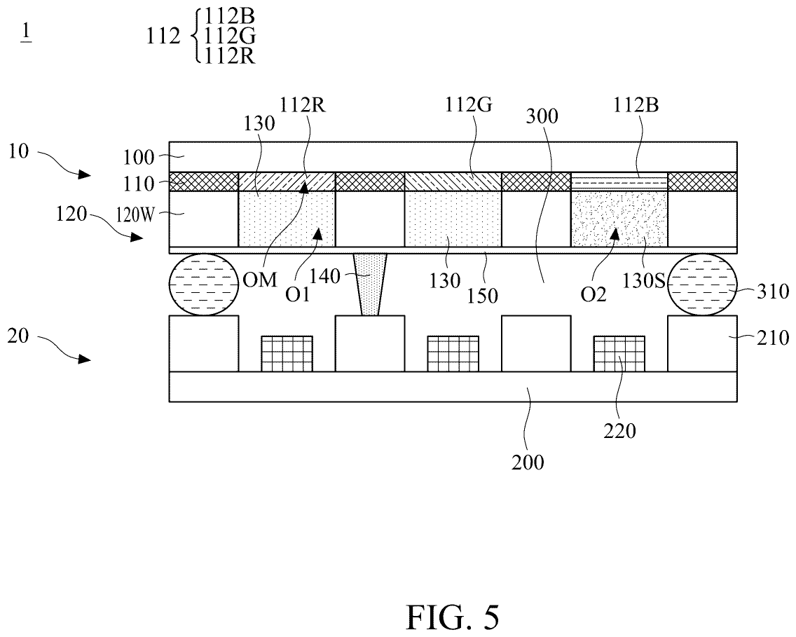

FIG. 4 illustrates a cross-sectional view of the light conversion structure 10 including the first substrate 100 and a spacer 140S formed in the second opening O2 of the bank layer 120 for forming the electronic device, in accordance with some other embodiments of the present disclosure. In such an embodiment, forming the light conversion structure 10 includes providing the first substrate 100 and forming the bank layer 120 on the first substrate 100. As shown in FIG. 4, the bank layer 120 may include the first opening O1 and the second opening O2. Then, the light conversion layer 130 may be formed in the first opening O1, and the spacer 140S may be formed in the second opening O2. After the spacer 140S is formed, the encapsulation layer 150 may be formed on the light conversion layer 130 and the spacer 140S.

In some embodiments, as shown in FIG. 4, before forming the bank layer 120, a black matrix layer 110 including a matrix opening OM is further formed on the first substrate 100. Then, the color filter layer 112 can be formed in the matrix opening OM. In some embodiments, as shown in FIG. 1A, the black matrix layer 110 is sandwiched between the first substrate 100 and the bank layer 120.

In some embodiments, as shown in FIG. 4, the height of the spacer 140S is greater than the height of the bank wall 120W. In some embodiments, the width of the top surface of the spacer 140S is greater than the width of the second opening O2. The material of the spacer 140S may be the same as or similar to the above-mentioned scattering layer 130S, and its detailed description is omitted here for the sake of simplicity. Specifically, the spacer 140S may include a plurality of light-absorbing particles or light-scattering particles, but it is not limited thereto. In some embodiments, the light conversion layer 130 is formed using an inkjet printing process. In some embodiments, the spacer 140S is formed using a photolithography process. The lithography process used to form the spacer 140S may be similar to the above-mentioned lithography process used to form the spacer 140, and its detailed description is omitted here for the sake of simplicity.

According to the embodiment of the light conversion structure 10 shown in FIG. 4, the spacer 140S filled in the second opening O2 can scatter the light from the color filter layer 112 (for example, the blue filter layer 112B) below. In addition, the spacer 140S can also serve as a spacer supported between the light conversion structure 10 and the electronic structure 20 provided subsequently. It should be understood that although the spacer 140S is illustrated in the second opening O2 on the blue filter layer 112B in FIG. 4, the present disclosure is not limited thereto. In other embodiments, the spacer 140S may also be formed on the color filter layer 112 corresponding to other wavelength ranges.

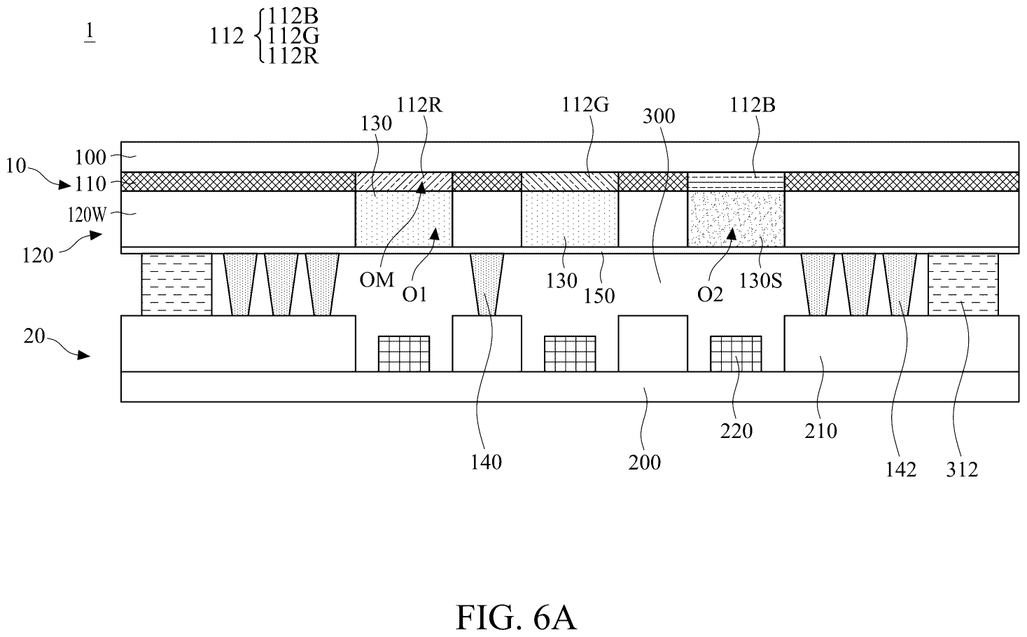

FIG. 5 illustrates a cross-sectional view of an electronic device 1 formed by overlapping the first substrate 100 and the second substrate 100, in accordance with some embodiments of the present disclosure. The method for manufacturing the electronic device 1 of the present disclosure further includes the formation of the electronic structure 20. Specifically, the electronic device 1 may be formed by bonding the light conversion structure 10 and the electronic structure 20 to each other, but it is not limited thereto. The structure of the electronic structure 20 and its formation method will be described below.

As a method for forming the electronic structure 20, first the second substrate 200 may be provided. Then, a plurality of electronic units 220 may be transferred to the second substrate 200. The present disclosure does not limit the elements used as the electronic units 220. For example, the electronic units 220 may be elements with a light-emitting function, such as organic light-emitting diodes (OLEDs), sub-millimeter light-emitting diodes (mini LEDs), or micro light-emitting diodes (micro LEDs) or quantum dot light-emitting diodes (quantum dot LEDs), other suitable light-emitting elements, or a combination thereof, but is not limited to this.

In some embodiments, a pixel definition layer 210 is formed on the second substrate 200, thereby defining the position, size, and distribution of the pixels of the electronic device 1. The material of the pixel definition layer 210 may include, for example, black resin, gray resin, white resin, metal, other suitable materials, or a combination of the above materials, but it is not limited thereto. The formation method of the pixel definition layer 210 may include physical vapor deposition (PVD), chemical vapor deposition (CVD), atomic layer deposition (ALD), electron beam evaporation, electroplating, inkjet printing, sol-gel method, photoresist coating, other suitable methods, or a combination thereof, but not limited to this. In some embodiments, the pixel definition layer 210 is formed using a lithography process, but the disclosure is not limited thereto.

After forming the light conversion structure 10 and the electronic structure 20 respectively, the light conversion structure 10 and the electronic structure 20 may be bonded to form the electronic device 1. As a result, the first substrate 100 and the second substrate 200 may be overlapped so that the spacer 140 is located between the first substrate 100 and the second substrate 200.

Before overlapping the first substrate 100 and the second substrate 200, the method for manufacturing the electronic device 1 may further include coating an adhesive material 300 and a frame glue 310 on one of the first substrate 100 and the second substrate 200, and the frame glue 310 may surround the adhesive material 300. Although the spacer 140 in FIG. 5 is located on the encapsulation layer 150 and disposed in the adhesive material 300, the present disclosure is not limited thereto. In other embodiments, the encapsulation layer 150 covers the spacer 140 and separates the spacer 140 from the adhesive material 300.

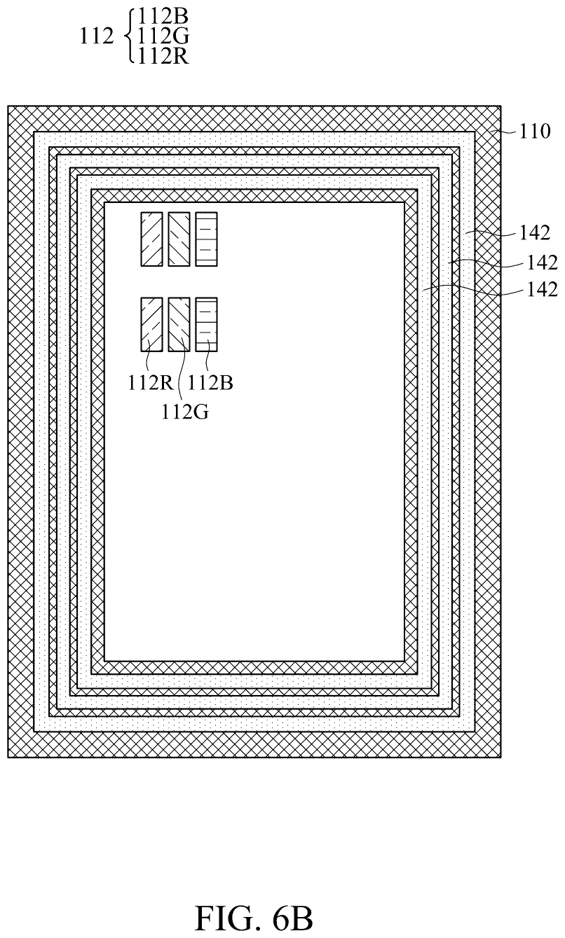

In addition, although FIG. 5 shows a cross-section of the frame glue 310 that is spherical in the direction perpendicular to the first substrate 100 and the second substrate 200, the present disclosure does not limit the shape of the frame glue 310 in the cross-section. Depending on the method used to form the frame glue, the frame glue of the electronic device 1 may have other shapes in the cross-section, such as rectangle (refer to the frame glue 312 in FIG. 6A below), trapezoid, etc., but it is not limited thereto. The adhesive material 300 may include light-transmitting materials, such as silicone resin, epoxy resin, acrylic resin, other suitable materials, or combinations thereof, but it is not limited thereto. The material of the frame glue 310 may include, for example, acrylic resin, epoxy resin, other suitable materials, or a combination thereof, but it is not limited thereto.

The formation method of the adhesive material 300 may include inkjet printing, sol-gel method, photoresist coating, other suitable methods, or a combination thereof, but it is not limited thereto. The formation method of the frame glue 310 may include physical vapor deposition (PVD), chemical vapor deposition (CVD), atomic layer deposition (ALD), electron beam evaporation, electroplating, inkjet printing, sol-gel method, photoresist coating, other suitable methods, or combinations thereof, but are not limited to this. In some embodiments, the frame glue 310 is formed by screen printing, but the present disclosure is not limited thereto.

Compared with traditional electronic devices that use inkjet printing technology to form spacers, since the spacer 140 of the present disclosure has a larger elastic recovery rate, its shape is not likely to deform when joining two substrates. As a result, the spacer 140 can provide stable and uniform support throughout the entire electronic device 1, thereby improving the quality and yield of the electronic device. In addition, by forming the spacer 140 between the first substrate 100 and the second substrate 200 through the method disclosed above, the electronic device 1 can be manufactured with greater throughput, which is beneficial to the mass production of the electronic device 1.

FIG. 6A illustrates a cross-sectional view of the electronic device 1 formed by overlapping the first substrate 100 and the second substrate 200, in accordance with some embodiments of the present disclosure. In some embodiments, a spacer 142 is disposed adjacent to the frame glue 312. In some embodiments, the spacer 142 adjacent to the frame glue 312 may have multiple layers. FIG. 6B illustrates a schematic top view of the electronic device 1, in accordance with some embodiments of the present disclosure. FIG. 6B shows the relative positions of the black matrix layer 110, the spacer 142, and the color filter layers 112 in the top view direction of the first substrate 100 and the second substrate 200. It should be understood that other components of the electronic device 1 have been omitted in FIG. 6B for the sake of simplicity. As shown in FIG. 6B, the spacer 142 may surround a plurality of color filter layers 112. By disposing the spacer 142 adjacent to the frame glue 312, the impact of the adhesive material 300 on the frame glue 312 can be reduced and the adhesive material 300 can be prevented from penetrating near the frame glue 312.

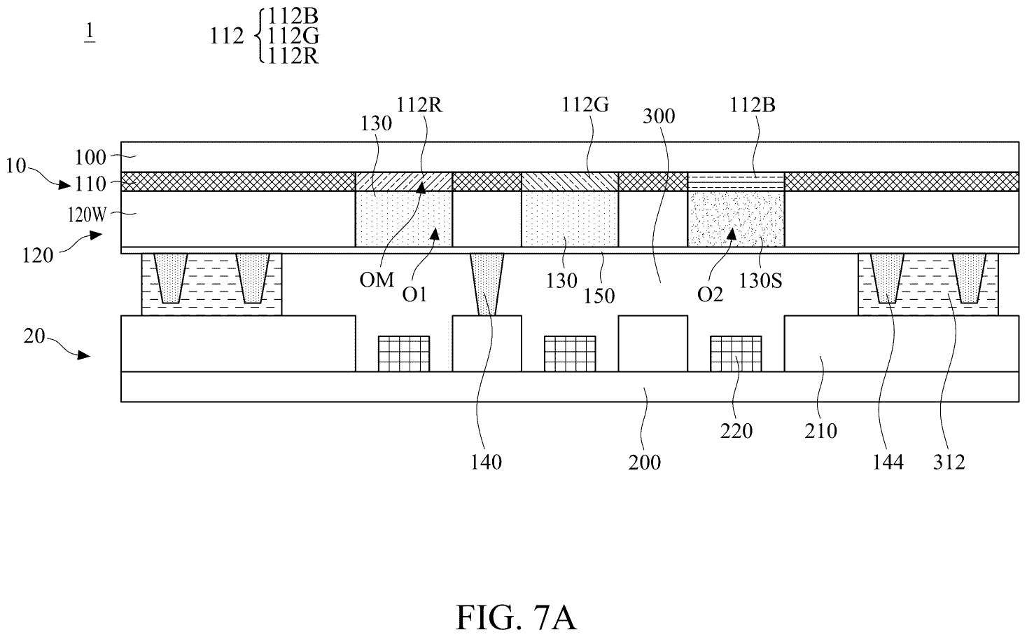

FIG. 7A illustrates a cross-sectional view of the electronic device 1 formed by overlapping the first substrate 100 and the second substrate 200, in accordance with some embodiments of the present disclosure. In some embodiments, the spacers of the electronic device 1 may include first spacers (e.g., spacers 140) disposed in the adhesive material 300 and second spacers (e.g., spacers 144) disposed in the frame glue 312. In some embodiments, the height of the second spacers is less than the height of the first spacers. FIG. 7B illustrates a schematic top view of the electronic device 1, in accordance with some embodiments of the present disclosure. FIG. 7B shows the relative positions of the black matrix layer 110, the spacer 144, and the color filter layers 112 in the top view direction of the first substrate 100 and the second substrate 200. It should be understood that other components of the electronic device 1 have been omitted in FIG. 7B for the sake of simplicity.

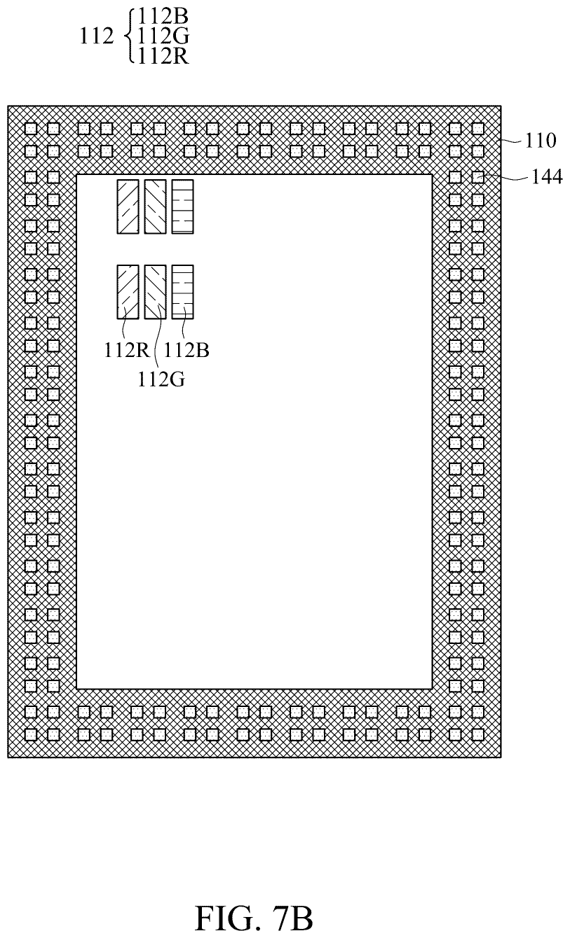

FIG. 8 illustrates a cross-sectional view of a stage in the method for manufacturing the electronic device 1 where the first substrate 100 and the second substrate 200 are cut to form multiple electronic panels, in accordance with some embodiments of the present disclosure. Specifically, after overlapping the first substrate 100 and the second substrate 200, the method for manufacturing the electronic device 1 further includes cutting the first substrate 100 and the second substrate 200 along the line L to form the multiple electronic panels. Although the two electronic panels shown in FIG. 8 have the same configuration, the present disclosure is not limited thereto. For example, a person with ordinary skill in the art may determine the configuration of each electronic panel according to the design requirements of the electronic device 1, such as different spacer configurations, positional relationships between the encapsulation layer and the spacer, or other adjustments in different electronic panels, but not limited to this.

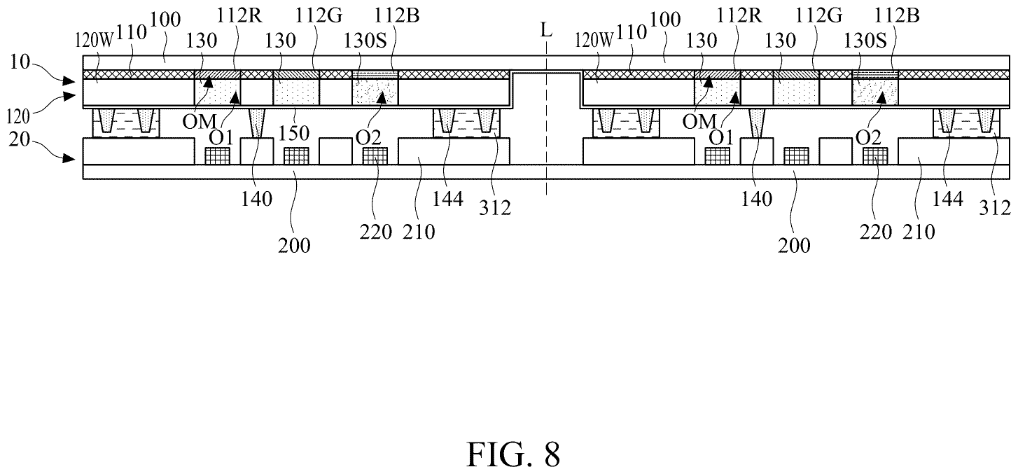

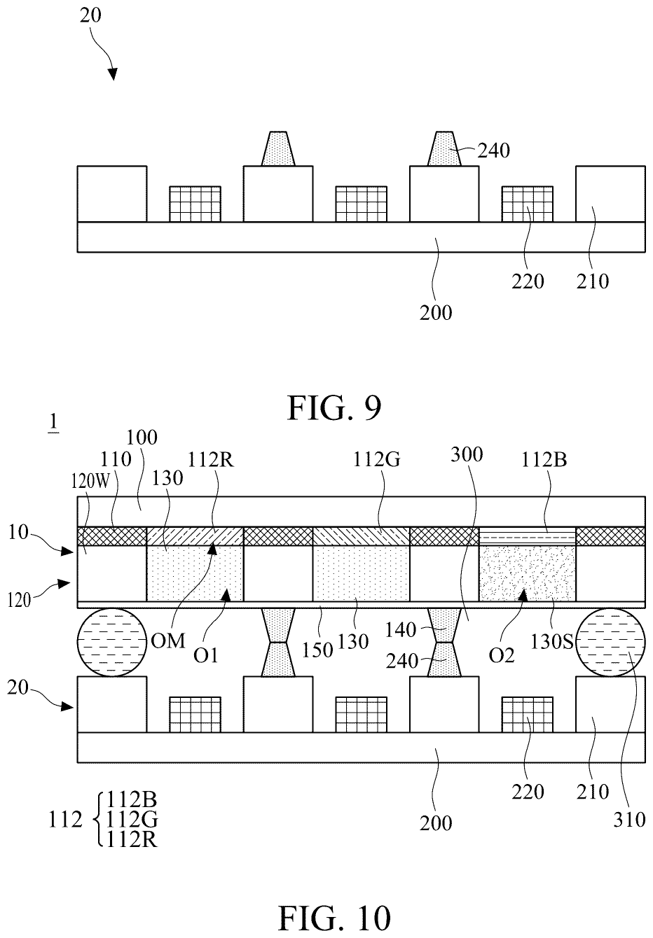

FIG. 9 illustrates a cross-sectional view of the electronic structure 20 including the second substrate 200 and a spacer 240 formed on the pixel definition layer 210 for forming the electronic device 20, in accordance with some embodiments of the present disclosure. As shown in FIG. 9, in addition to forming the spacer on the bank layer of the light conversion structure (e.g., the spacer 140 discussed above), the spacers 240 may also be formed on the pixel defining layer 210 of the electronic structure 20. Thereby, the light conversion structure and the electronic structure, are bonded together in the subsequent bonding process, wherein there are spacers in both of the light conversion structure and the electronic structure, so that the electronic device 1 has a multi-layer spacer structure. FIG. 10 illustrates a cross-sectional view of the electronic device 1 formed by overlapping the first substrate 100 and the second substrate 200, in accordance with some embodiments of the present disclosure. By forming the electronic device 1 with the spacers 140, 240 from the light conversion structure and the electronic structure respectively, the tops of the spacers 140, 240 can fit to each other.

In summary, the present disclosure provides a method for manufacturing an electronic device. A spacer is formed on a bank layer or in an opening of the bank layer, so that the spacer is located between two substrates of the resulting electronic device. Compared with traditional electronic devices that use inkjet printing technology to form spacers, since the spacers of the present disclosure have a greater elastic recovery rate, their shapes are not easily deformed when joining the two substrates. As a result, the spacer can provide stable and uniform support throughout the entire electronic device, thereby improving the quality and yield of the electronic device. In addition, by forming spacers between substrates through the method of the present disclosure, electronic devices can be manufactured with greater throughput, which is beneficial to mass production of electronic devices. Therefore, the present disclosure provides a method for manufacturing an electronic device that can improve the mass production of the electronic device while improving the quality and yield of the electronic device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an electronic device, comprising:
providing a first substrate;
forming a bank layer on the first substrate, wherein the bank layer comprises a bank wall and a first opening, and the first opening adjacent to the bank wall;
forming a light conversion layer in the first opening;
forming a spacer on the bank wall;
providing a second substrate;
transferring a plurality of electronic units to the second substrate; and
overlapping the first substrate and the second substrate, so that the spacer is located between the first substrate and the second substrate.

2. The method as claimed in claim 1, further comprising forming an encapsulation layer on the light conversion layer and the spacer.

3. The method as claimed in claim 1, wherein before forming the spacer on the bank wall, the method further comprises:
forming an encapsulation layer on the bank layer and the light conversion layer.

4. The method as claimed in claim 3, wherein the highest processing temperature for the spacer is lower than 120° C.

5. The method as claimed in claim 1, wherein the bank layer further comprises a second opening, with the bank wall located between the first opening and the second opening, and before forming the spacer on the bank wall, the method further comprises:
forming an encapsulation layer on the bank layer and the light conversion layer and in the second opening.

6. The method as claimed in claim 5, further comprising forming a scattering layer on a portion of the encapsulation layer located in the second opening.

7. The method as claimed in claim 6, wherein the spacer and the scattering layer are formed in the same lithography process.

8. The method as claimed in claim 1, wherein the spacer is formed using a lithography process.

9. The method as claimed in claim 1, wherein the light conversion layer is formed using an inkjet printing process.

10. The method as claimed in claim 1, wherein before forming the bank layer on the first substrate, the method further comprises:
forming a black matrix layer on the first substrate, wherein the black matrix layer comprises a matrix opening; and
forming a color filter layer in the matrix opening.

11. The method as claimed in claim 1, wherein after overlapping the first substrate and the second substrate, the method further comprises:
cutting the first substrate and the second substrate to form multiple electronic panels.

12. The method as claimed in claim 1, wherein before overlapping the first substrate and the second substrate, the method further comprises:
coating an adhesive material and a frame glue on one of the first substrate and the second substrate, with the frame glue surrounding the adhesive material.

13. The method as claimed in claim 12, wherein the spacer comprises a first spacer and a second spacer, and the first spacer is disposed in the adhesive material, and the second spacer is disposed in the frame glue.

14. The method as claimed in claim 13, wherein a height of the second spacer is lower than a height of the first spacer.

15. A method for manufacturing an electronic device, comprising:
providing a first substrate;
forming a bank layer on the first substrate, wherein the bank layer comprises a first opening, a second opening and a bank wall located between the first opening and the second opening;
forming a light conversion layer in the first opening;
forming a spacer in the second opening;
forming an encapsulation layer on the light conversion layer and the spacer;
providing a second substrate;
transferring a plurality of electronic units to the second substrate; and
overlapping the first substrate and the second substrate, so that the spacer is located between the first substrate and the second substrate.

16. The method as claimed in claim 15, wherein a height of the spacer is greater than a height of the bank wall.

17. The method as claimed in claim 15, wherein the spacer is formed using a lithography process.

18. The method as claimed in claim 15, wherein the light conversion layer is formed using an inkjet printing process.

19. The method as claimed in claim 15, wherein the spacer comprises a plurality of light-absorbing particles or light-scatter particles.

20. The method as claimed in claim 15, wherein before forming the bank layer, the method further comprises:
forming a black matrix layer on the first substrate, wherein the black matrix layer comprises a matrix opening, and the matrix opening overlaps the first opening or the second opening; and
forming a color filter layer in the matrix opening.
